(19) United States
(12) Patent Application Publication
(10) Pub. No.: US 2006/0005929 A1
(43) Pub. Date: Jan. 12, 2006

(54) Plasma processing device and plasma generating method

(76) Inventors: Nobuo Ishii, Hyogo (JP); Yasuyoshi Yasaka, Kyoto (JP); Masaharu Takahashi, Chiba (JP); Makoto Ando, Kanagawa (JP)

Correspondence Address: Irell & Manella, Suite 400, 840 Newport Center Drive, Newport Beach, CA, 92660, US

(21) Appl. No.: 10/507,053

(22) PCT Filed: Mar. 12, 2003
(86) PCT No.: PCT/JP03/02925

§ 371 Date: Aug. 4, 2005

(30) Foreign Application Priority Data
Mar. 12, 2002 (JP) 2002-066518

(51) Int. Cl. C23F 1/00; C23C 16/00

(52) U.S. Cl. 156/345.49; 118/723 I

(57) ABSTRACT

The length (L) of a slot (26) increases monotonously from the central portion (A) of an antenna surface (28) in the radial direction, and reaches the maximal value at the first intermediate portion (C). The maximal value is maintained from the first intermediate portion (C) until the peripheral portion (B). When compared to a case wherein the length of the slot is increased monotonously from the central portion of the antenna surface (28) until its peripheral portion, the power radiated from a slot antenna can increase. Accordingly, the power which is not radiated from the slot antenna but remains in it decreases, so that the reflected power from the slot antenna decreases.

### BACKGROUND OF THE INVENTION

The present invention relates to a plasma processing device and plasma generating method and, more particularly, to a plasma processing device and plasma generating method which supply an electromagnetic field into a processing vessel by using a slot antenna to generate a plasma.

In the manufacture of a semiconductor device or flat panel display, plasma processing devices are used often to perform processes such as formation of an oxide film, crystal growth of a semiconductor layer, etching, and ashing. Among the plasma processing devices, a high-frequency plasma processing device is available which supplies a high-frequency electromagnetic field into a processing vessel and ionizes and dissociates a gas in the processing vessel by the effect of the electromagnetic field, thus generating a plasma. The high-frequency plasma processing device can perform a plasma process efficiently since it can generate a low-pressure, high-density plasma.

FIG. 8 is a view showing an arrangement of an electromagnetic field supply device conventionally used to supply a high-frequency electromagnetic field into a processing vessel. An electromagnetic field supply device 510 shown in FIG. 8 includes a high-frequency generator 511 which generates a high-frequency electromagnetic field, a cylindrical waveguide 512 having one end connected to the high-frequency generator 511, a circular polarization converter 513 and load matching unit 514 provided to the cylindrical waveguide 512, and a radial line slot antenna (to be abbreviated as RLSA hereinafter) 515 connected to the other end of the cylindrical waveguide 512.

The RLSA 515 supplies the high-frequency electromagnetic field introduced from the cylindrical waveguide 512 into a processing vessel (not shown). More specifically, the RLSA 515 has two parallel circular conductor plates 522 and 523 which form a radial waveguide 521, and a conductor ring 524 which connects the edge portions of the two conductor plates 522 and 523 to shield the high-frequency electromagnetic field. An opening 525, through which the high-frequency electromagnetic field is introduced from the cylindrical waveguide 512 to the radial waveguide 521, is formed at the central portion of the conductor plate 522. A plurality of slots 526, through which the high-frequency electromagnetic field propagating in the radial waveguide 521 is supplied into the processing vessel, are formed in the conductor plate 523. The conductor plate 523 and slots 526 form an antenna surface 528.

The high-frequency electromagnetic field generated by the high-frequency generator 511 propagates in the cylindrical waveguide 512 in the TE₁₁ mode, is converted into a rotating electromagnetic field by the circular polarization converter 513, and is introduced to the RLSA 515. The high-frequency electromagnetic field introduced to the RLSA 515 is supplied into the processing vessel through the slots 526 while it propagates in the radial waveguide 521 radically. In the processing vessel, the supplied high-frequency electromagnetic field ionizes the gas to generate a plasma, so that a target object is processed with the plasma.

Part of the high-frequency electromagnetic field which is not supplied into the processing vessel returns from the RLSA 515 through the circular polarization converter 513 as a reflected electromagnetic field F1. The load matching unit 514 matches the impedance between the supply side and load side. Thus, the reflected electromagnetic field F1 is reflected by the load matching unit 514 again, and is phase-matched with a traveling wave supplied from the high-frequency generator 511, so that a power can be additionally supplied to the RLSA 515.

When the power (reflected power) of the reflected electromagnetic field F1 increases, the load matching unit 514 cannot reflect the total power of the reflected electromagnetic field F1, and a standing wave is generated between the high-frequency generator 511 and load matching unit 514. Consequently, the cylindrical waveguide 512 may be deformed as it is locally heated by the standing wave between the high-frequency generator 511 and load matching unit 514. Also, the power may not be supplied to the load side of the RLSA 515 efficiently.

### SUMMARY OF THE INVENTION

The present invention has been made to solve these problems, and has as its object to decrease the reflected power from the slot antenna.

In order to achieve the above object, according to the present invention, there is provided a plasma processing device characterized by comprising a table for placing a target object thereon, a processing vessel for accommodating the table, and a slot antenna arranged to oppose the table to supply an electromagnetic field into the processing vessel, wherein radiation coefficients of a plurality of slots formed in an antenna surface of the slot antenna increase monotonously in a radial direction of the antenna surface from a central portion of the antenna surface until a first intermediate portion on the way to a peripheral portion, and maintain values obtained at the first intermediate portion from the first intermediate portion toward the peripheral portion.

The lengths of the slots may change monotonously from the central portion until the first intermediate portion of the antenna surface, and maintain lengths obtained at the first intermediate portion from the first intermediate portion toward the peripheral portion.

When lengths L of the slots satisfy:
L≦λg/2
or

(N/2+¼)×λg≦L≦(N+1)×λg/2 (N is a natural number) where λg is a wavelength of an electromagnetic field in the slot antenna, the lengths of the slots may increase monotonously from the central portion until the first intermediate portion.

Alternatively, from an innermost slot of the antenna surface until an arbitrary slot of the antenna surface in the radial direction, a length of each slot may be larger than that of a slot inside each slot, and from the arbitrary slot toward an outermost slot of the antenna surface, the length of each slot may be equal to that of the arbitrary slot.

When the lengths L of the slots satisfy:

N×λg/2≦L≦(N/2+¼)×λg (N is a natural number), the lengths of the slots may decrease monotonously from the central portion until the first intermediate portion.

Alternatively, from an innermost slot of the antenna surface until an arbitrary slot of the antenna surface in the radial direction, a length of each slot may be smaller than that of a slot inside each slot, and from the arbitrary slot toward an outermost slot of the antenna surface, the length of each slot may be equal to that of the arbitrary slot.

In the plasma processing device described above, in the radial direction of the antenna surface, the radiation coefficients of the slots may maintain values obtained at the first intermediate portion from the first intermediate portion of the antenna surface until the second intermediate portion on the way to the peripheral portion, and may decrease monotonously from the second intermediate portion until the peripheral portion.

Lengths of the slots may change monotonously from the central portion until the first intermediate portion of the antenna surface, may maintain lengths obtained at the first intermediate portion from the first intermediate portion until the second intermediate portion, and may change monotonously from the second intermediate portion until the peripheral portion, inversely to the slots from the central portion until the first intermediate portion.

When the lengths L of the slots satisfy:
L≦λg/2
or

(N/2+¼)×λg≦L≦(N+1)×λg/2 (N is a natural number), the lengths of the slots may decrease monotonously from the second intermediate portion until the peripheral portion.

Alternatively, from an innermost slot of the antenna surface until a slot at the first intermediate portion of the antenna surface in the radial direction, a length of each slot may be larger than that of a slot inside each slot, from the slot at the first intermediate portion until a slot at the second intermediate portion in the radial direction, the length of each slot may be equal to that of the slot at the first intermediate portion, and from the slot at the second intermediate portion until an outermost slot in the radial direction, the length of each slot may be smaller than that of a slot inside each slot.

When the lengths L of the slots satisfy:

N×λg/2≦L≦(N/2+¼)×λg (N is a natural number), the lengths of the slots may increase monotonously from the second intermediate portion until the peripheral portion.

Alternatively, from an innermost slot of the antenna surface until a slot at the first intermediate portion of the antenna surface in the radial direction, a length of each slot may be smaller than that of a slot inside each slot, from the slot at the first intermediate portion until a slot at the second intermediate portion in the radial direction, the length of each slot may be equal to that of the slot at the first intermediate portion, and from the slot at the second intermediate portion until an outermost slot in the radial direction, the length of each slot may be larger than that of a slot inside each slot.

A plasma generating method of the present invention is characterized in that when an electromagnetic field is supplied into a processing vessel by using a slot antenna in which a plurality of slots are formed in an antenna surface thereof, to generate a plasma, radiation coefficients of the slots are increased monotonously from a central portion of the antenna surface until the first intermediate portion on the way to a peripheral portion in a radial direction of the antenna surface, and values of the radiation coefficients obtained at the first intermediate portion are maintained from the first intermediate portion toward the peripheral portion.

The values of the radiation coefficients obtained at the first intermediate portion may be maintained from the first intermediate portion of the antenna surface until a second intermediate portion on the way to the peripheral portion in the radial direction of the antenna surface, and the radiation coefficients may be decreased monotonously from the second intermediate portion until the peripheral portion.

### BRIEF DESCRIPTION OF THE DRAWINGS

FIG. 1 is a view showing the overall arrangement of a plasma processing device according to the first embodiment of the present invention;

FIG. 2A is a,plan view showing an arrangement of the antenna surface seen from the direction of a line II-II′ of FIG. 1, and FIG. 2B is a graph showing a change in the slot length with respect to a radial direction;

FIG. 3A is a view showing an example of an inverted-V-shaped slot, and FIG. 3B is a view showing an example of a cross slot;

FIGS. 4A to 4D are views each showing an example of the shape of a slot formed in the antenna surface;

FIG. 5A is a plan view showing an arrangement of the antenna surface of a slot antenna used in a plasma processing device according to the second embodiment of the present invention, and FIG. 5B is a graph showing a change in slot length with respect to a radial direction;

FIG. 6A is a longitudinal sectional view showing the arrangement of a radial line slot antenna having an antenna surface that forms an upwardly projecting circular cone, and FIG. 6B is a perspective view showing the arrangement of the antenna surface shown in FIG. 6A;

FIG. 7 is a perspective view showing the arrangement of an antenna surface that forms a downwardly projecting circular cone; and

FIG. 8 is a view showing an arrangement of a conventional electromagnetic field supply device.

### DESCRIPTION OF THE PREFERRED EMBODIMENTS

The embodiments of the present invention will be described with reference to the drawings.

### First Embodiment

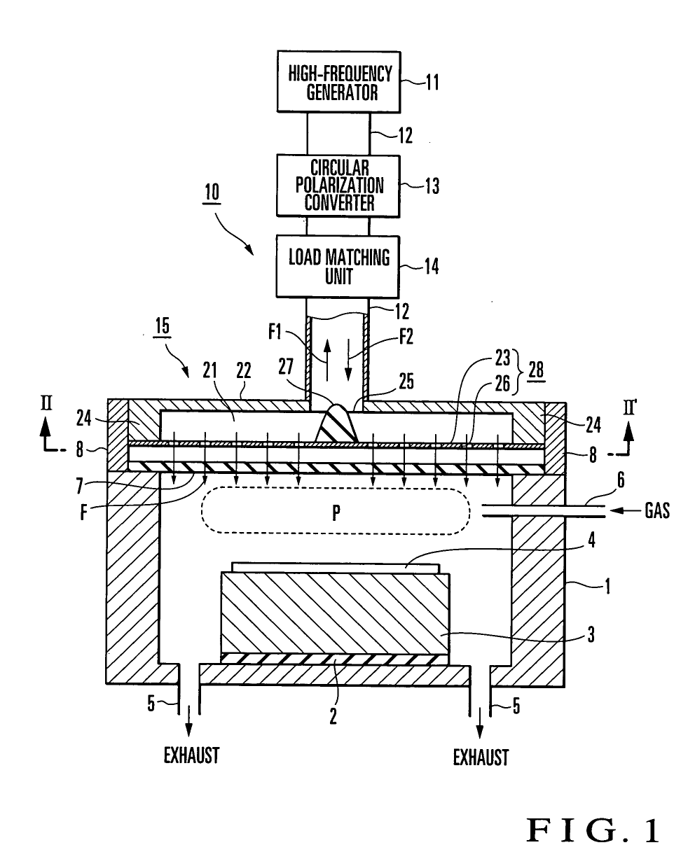

A plasma processing device according to the first embodiment of the present invention will be described with reference to FIGS. 1 to 4. FIG. 1 is a view showing the overall arrangement of the first embodiment. This plasma processing device has a processing vessel 1 which accommodates a substrate 4, e.g., a semiconductor or LCD, as a target object and processes the substrate 4 with a plasma, and an electromagnetic field supply device 10 which supplies a high-frequency electromagnetic field F into the processing vessel 1 so that a plasma P is generated in the processing vessel 1 by the operation of the high-frequency electromagnetic field F.

The processing vessel 1 is a bottomed cylinder with an upper opening. A substrate table (table) 3 is fixed to the central portion of the bottom surface of the processing vessel 1 through an insulating plate 2. The substrate 4 is placed on the upper surface of the substrate table 3.

Exhaust ports 5 for vacuum evacuation are formed in the periphery of the bottom surface of the processing vessel 1. A gas introducing nozzle 6 is arranged in the side wall of the processing vessel 1 to introduce a gas into the processing vessel 1. For example, when the plasma processing device is used as an etching device, a plasma gas such as Ar and an etching gas such as CF₄ are introduced into the device through the nozzle 6.

The upper opening of the processing vessel 1 is closed with a dielectric plate 7 so the plasma P generated in the processing vessel 1 will not leak outside. An RLSA 15 of the electromagnetic field supply device 10 is disposed on the dielectric plate 7. The outer surfaces of the dielectric plate 7 and RLSA 15 are covered by a shield member 8 annularly arranged on the side wall of the processing vessel 1, so that the high-frequency electromagnetic field F will not leak outside.

The electromagnetic field supply device 10 includes the RLSA 15 and a power feed unit of the RLSA 15. The power feed unit includes a high-frequency generator 11, a cylindrical waveguide 12 connected between the high-frequency generator 11 and RLSA 15, and a circular polarization converter 13 and load matching unit 14 provided to the cylindrical waveguide 12.

The high-frequency generator 11 generates and outputs the high-frequency electromagnetic field F having a predetermined frequency (e.g., 2.45 GHz) within the range of 1 GHz to ten-odd GHz. The high-frequency generator 11 may output high-frequency waves including a microwave and a frequency band lower than that.

The circular polarization converter 13 converts the high-frequency electromagnetic field F, propagating in the cylindrical waveguide 12 in the TE₁₁ mode, into a rotating electromagnetic field which rotates by one revolution in one period in a plane perpendicular to its traveling direction.

The load matching unit 14 matches the impedance of the supply side (high-frequency generator 11 side) and that of the load side (RLSA 15 side) of the cylindrical waveguide 12.

The RLSA 15 supplies the high-frequency electromagnetic field F, introduced from the cylindrical waveguide 12, into the processing vessel 1 through the dielectric plate 7. More specifically, the RLSA 15 has two parallel circular conductor plates 22 and 23 which form a radial waveguide 21, and a conductor ring 24 which connects the outer edges of the two conductor plates 22 and 23 to shield the high-frequency electromagnetic field F. The conductor plates 22 and 23 and the conductor ring 24 are made of a conductor such as copper or aluminum.

An opening 25 to be connected to the cylindrical waveguide 12 is formed at the central portion of the conductor plate 22 serving as the upper surface of the radial waveguide 21. The high-frequency electromagnetic field F is introduced into the radial waveguide 21 through the opening 25. A plurality of slots 26, through which the high-frequency electromagnetic field F propagating in the radial waveguide 21 is supplied into the processing vessel 1, are formed in the conductor plate 23 serving as the lower surface of the radial waveguide 21. The conductor plate 23 and slots 26 form an antenna surface 28.

A bump 27 made of a conductor or dielectric is arranged at the central portion on the antenna surface 28. The bump 27 is a substantially circular conical member projecting toward the opening 25 of the conductor plate 22. The bump 27 moderates a change in impedance from the cylindrical waveguide 12 to the radial waveguide 21, so that reflection of the high-frequency electromagnetic field F at the connecting portion of the cylindrical waveguide 12 and radial waveguide 21 can be decreased.

A wave delay member may be arranged in the radial waveguide 21. The wave delay member is made of a dielectric having a relative dielectric constant larger than 1. As the wave delay member decreases a wavelength λg in the radial waveguide 21, the number of slots 26 to be arranged in the antenna surface 28 in the radial direction can be increased, so that the supply efficiency of the high-frequency electromagnetic field F may be improved.

The antenna surface 28 of the RLSA 15 will be described in detail. A case will be described wherein the length of each slot 26 is set equal to or less than ½ the wavelength λg in the radial waveguide 21.

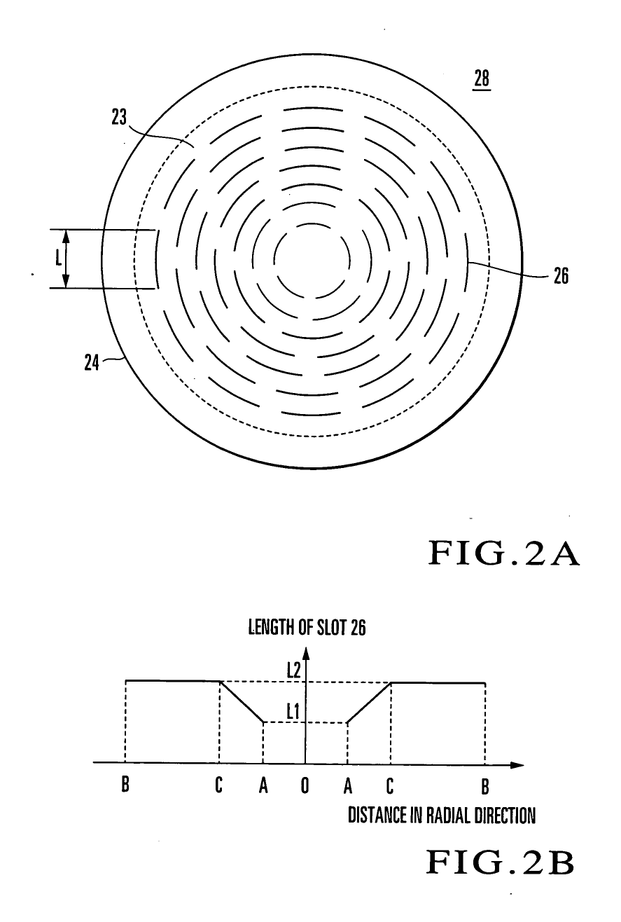

FIG. 2A is a plan view showing an arrangement of the antenna surface 28 seen from the direction of the line II-II′ of FIG. 1, and FIG. 2B is a graph showing a change in the length of the slot 26 with respect to the radial direction. Referring to FIG. 2B, the axis of abscissa represents a distance in the radial direction from a center O of the antenna surface 28, and the axis of ordinate represents a length L of the slot 26.

In FIG. 2A, the slots 26 extending in the circumferential direction are arranged concentrically.

As shown in FIG. 2B, assume that the central portion and peripheral portion of the antenna surface 28 are denoted by A and B, respectively, and that a predetermined position (to be referred to as the first intermediate portion hereinafter) on the way from the central portion A to the peripheral portion B is denoted by C. In the radial direction of the antenna surface 28, the lengths L of the slots 26 increase monotonously from L1 at the central portion A to reach maximal lengths L2 at the first intermediate portion C. The maximal lengths L2 are maintained from the first intermediate portion C until the peripheral portion B. Hence, from the innermost slot of the antenna surface 28 until an arbitrary slot in the radial direction, the length of each slot is larger than that of a slot inside it. Also, from the arbitrary slot until the outermost slot of the antenna surface 28, the length of each slot is equal to that of the arbitrary slot. Note that 0<L1<L2≦λg/2.

The ratio of the power of the high-frequency electromagnetic field F in the radial waveguide 21 near a slot 26 to the power (radiation power) of the high-frequency electromagnetic field F radiated (or leaking) through the slot 26 is defined as the radiation coefficient of the slot 26. More specifically, the radiation coefficient is expressed by (radiation power)/(power in the radial waveguide 21), and increases gradually as the length L of the slot 26 increases from zero (0) to reach a maximum λg/2.

Hence, when the length L of the slot 26 is changed as described above with respect to the radial direction of the antenna surface 28, the radiation coefficient of the slot 26 increases monotonously from the central portion A of the antenna surface 28 in the radial direction, and reaches the maximal value at the first intermediate portion C. The maximal value is maintained from the first intermediate portion C until the peripheral portion B. In this manner, when compared to a case wherein the radiation coefficient of the slot is increased monotonously, the power radiated (or leaking) from the RLSA 15 while the high-frequency electromagnetic field F propagates from the central portion to the peripheral portion of the radial waveguide 21 increases. Accordingly, the power which is not radiated from the RLSA 15 but remains in the radial waveguide 21 decreases, so that the reflected power of the reflected electromagnetic field F1 which returns through the cylindrical waveguide 12 from the radial waveguide 21 decreases.

Therefore, impedance matching with the load matching unit 14 becomes easy. The total power of the reflected electromagnetic field F1 can be reflected by the load matching unit 14 again, and is phase-matched with a traveling wave supplied from the high-frequency generator 11, so that a power can be additionally supplied to the RLSA 15. Hence, no standing wave is generated between the high-frequency generator 11 and load matching unit 14, and the cylindrical waveguide 12 will not be deformed by being locally heated between the high-frequency generator 11 and load matching unit 14. Also, the power will not be consumed except at the load side portion, so that the power can be supplied into the processing vessel 1 efficiently.

In the above description, a case is described wherein the length L of the slot 26 is ½ or less the wavelength λg in the radial waveguide 21. When the length L of the slot 26 falls within the range of relation (1), the radiation coefficient also increases gradually as the length L of the slot 26 becomes larger than (N/2+¼)×λg, and becomes maximum when the length L is (N+1)×λg/2. Thus, when the lengths L of the slots 26 are set in the same manner, the power returning from the radial waveguide 21 to the cylindrical waveguide 12 can be decreased.
(N/2+¼)×λg≦L≦(N+1)×λg/2 (1)
where N is a natural number (this applies to the following description).

When the length L of the slot 26 falls within the range of relation (2), the radiation coefficient of the slot 26 gradually increases as the length L of the slot 26 becomes smaller than (N/2+¼)×λg, and becomes maximal when the length L is N×λg/2. Hence, the length L of the slot 26 is decreased monotonously from the central portion A until the first intermediate portion C in the radial direction of the antenna surface 28, and the length (the minimal length of L) obtained at the first intermediate portion C is maintained from the first intermediate portion C until the peripheral portion B. In this case, from the innermost slot until an arbitrary slot of the antenna surface 28 in the radial direction, the length of each slot is smaller than that of a slot inside it. From the arbitrary slot to the outermost slot of the antenna surface 28, the length of each slot is equal to that of the arbitrary slot.
N×λg/2≦L≦(N/2+¼)×λg (2)

In this manner, when the length L of the slot 26 is changed, the radiation coefficient of the slot 26 increases monotonously from the central portion A of the antenna surface 28 in the radial direction to reach a maximal value at the first intermediate portion C. The maximal value is maintained from the first intermediate portion C until the peripheral portion B. When this RLSA is used, the power returning from the radial waveguide 21 through the cylindrical waveguide 12 can be decreased.

In FIG. 2B, the length L of the slot 26 changes as a linear function between A and C, but the present invention is not limited to this. Regarding the position of the first intermediate portion C, an appropriate position is selected in accordance with the process conditions and the like.

FIG. 2A shows an example in which the slots 26 extending in the circumferential direction are arranged concentrically. Alternatively, the slots 26 may be arranged to form swirls, or slots 26 extending in the radial direction may be formed.

The interval of the radially adjacent slots 26 may be set to about λg so that the RLSA 15 forms a radial antenna, or about λg/3 to λg/40 so that the RLSA 15 forms a leakage antenna.

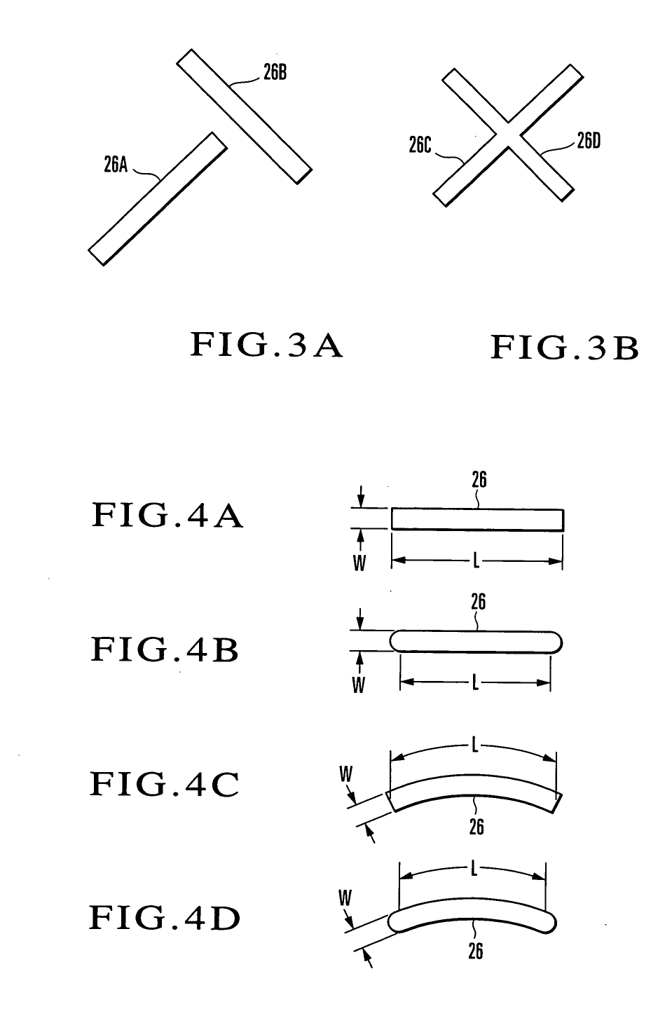

A plurality of so-called inverted-V-shaped slots, in each of which the extension line of one slot 26A intersects the other slot 26B or the extension line of the other slot 26B, as shown in FIG. 3A, or a plurality of cross slots, each including two different-length slots 26C and 26D that intersect at their centers, as shown in FIG. 3B, may be formed in the antenna surface 28, to radiate a circularly polarized wave into the processing vessel 1.

Regarding the planar shape of the slot 26, a rectangle as shown in FIG. 4A may be employed, or a shape as shown in FIG. 4B may be employed in which the two ends on one side of two parallel straight lines are connected to the two ends on the other side with curves such as arcs. Alternatively, a shape as shown in FIG. 4C or 4D may be employed in which the long sides of the rectangle of FIG. 4A or the two parallel straight lines of FIG. 4B are arcuated. The length L of the slot is the length of each long side of the rectangle in FIG. 4A, and is the length of each of the two parallel straight lines in FIG. 4B. A width W of the slot 26 may be set to about 2 mm by considering the influence on the high-frequency electromagnetic field F in the radial waveguide 33 and the wavelength of the radial waveguide 33.

### Second Embodiment

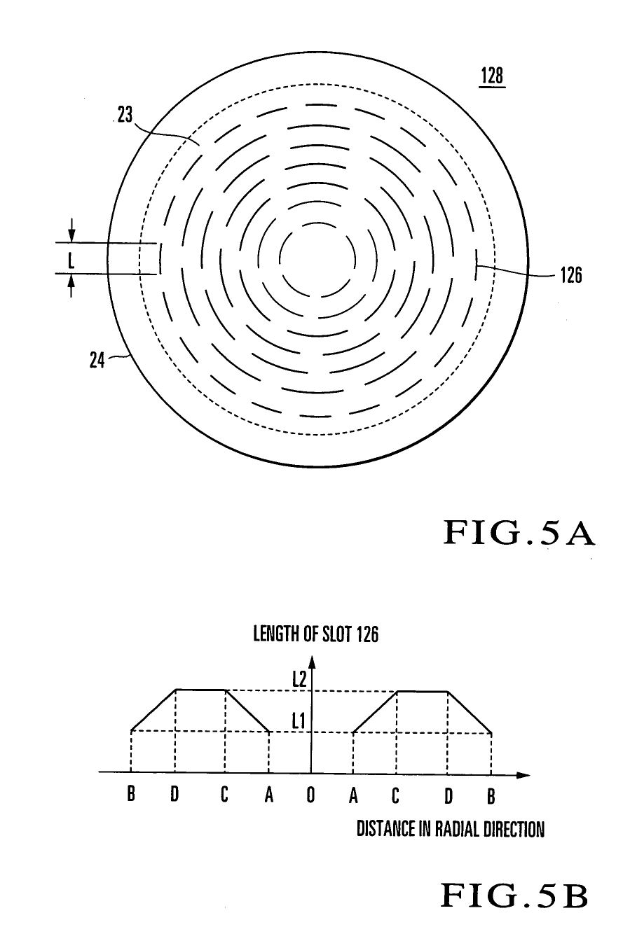

A plasma processing device according to the second embodiment of the present invention will be described with reference to FIGS. 5A and 5B. FIG. 5A is a plan view showing an arrangement of the antenna surface of an RLSA used in this embodiment, and FIG. 5B is a graph showing a change in the length of the slot with respect to the radial direction. In FIGS. 5A and 5B, the same or identical portions as in FIGS. 2A and 2B are denoted by the same reference numerals, and a description thereof will be omitted when appropriate. FIG. 5A corresponds to FIG. 2A.

As shown in FIG. 5, assume that a predetermined position (to be referred to as the second intermediate portion hereinafter) on the way from a first intermediate portion C to a peripheral portion B of an antenna surface 128 is denoted by D. In the radial direction of the antenna surface 128, lengths L of slots 126 increase monotonously from lengths L1 at a central portion A to reach maximal lengths L2 at the first intermediate portion C. The maximal lengths L2 are maintained from the first intermediate portion C until the second intermediate portion D, and decrease monotonously from the second intermediate portion D until the peripheral portion B. Hence, from the innermost slot of the antenna surface 128 until the first intermediate portion C in the radial direction, the length of each slot is larger than that of a slot inside it. Also, from the slot at the first intermediate portion C until the slot at the second intermediate portion D in the radial direction, the length of each slot is equal to that of the slot at the first intermediate portion C. From the slot at the second intermediate portion D until the outermost slot in the radial direction, the length of each slot is smaller than that of the slot inside it.

Assume that the lengths L of the slots 126 are set equal to or less than ½ a wavelength λg of a radial waveguide 21. In this case, near the peripheral portion of the antenna surface 128, the lengths L of the slots 126 are decreased monotonously conversely to the case from the central portion A until the first intermediate portion C. Then, the radiation coefficients of the slots 126 also decrease monotonously, and the radiation power of a high-frequency electromagnetic field F near the peripheral portion decreases. Consequently, the field strength near the side wall of a processing vessel 1 decreases, so that plasma generation by ionization of the plasma gas is suppressed. If the plasma density in the processing vessel 1 near the side wall is high, it is decreased. Then, contamination in the processing vessel 1 caused when a plasma P comes into contact with the side wall of the processing vessel 1 to sputter the metal surface can be decreased.

In the above description, the lengths L of the slots 126 are set equal to or less than ½ the wavelength λg in the radial waveguide 21. This also applies to a case wherein the slots 126 are formed such that their lengths L fall within the range of relation (1).

Assume that the slots 126 are to be formed such that their lengths L fall within the range of relation (2). In this case, in the radial direction of the antenna surface 128, the lengths L of the slots 126 are inversely decreased monotonously from the central portion A until the first intermediate portion C. The lengths (minimal lengths of L) at the first intermediate portion C are maintained from the first intermediate portion C until the second intermediate portion D, and are increased monotonously from the second intermediate portion D until the peripheral portion B. In this case, from the innermost slot of the antenna surface 128 until the slot at the first intermediate portion C in the radial direction, the length of each slot is smaller than that of a slot inside it. Also, from the slot at the first intermediate portion C until the slot at the second intermediate portion D in the radial direction, the length of each slot is equal to that of the slot at the first intermediate portion C. From the slot at the second intermediate portion D until the outermost slot in the radial direction, the length of each slot is larger than that of the slot inside it. When the lengths L of the slots 126 are changed in this manner, the radiation coefficients of the slots 126 decrease monotonously near the periphery of the antenna surface 128, so that contamination in the processing vessel 1 can be decreased.

In FIG. 5B, the length L of the slot 126 changes as a linear function between D and B, but the present invention is not limited to this. Although the length L of the slot 126 decreases to L1 at the peripheral portion B, it need not be decreased to L1. Regarding the position of the second intermediate portion D, an appropriate position is selected in accordance with process conditions and the like.

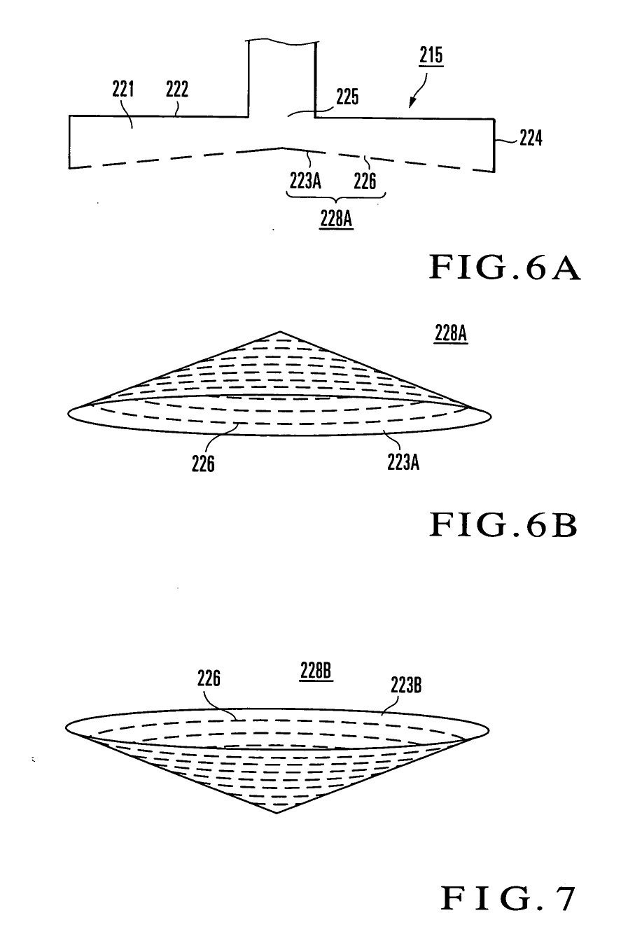

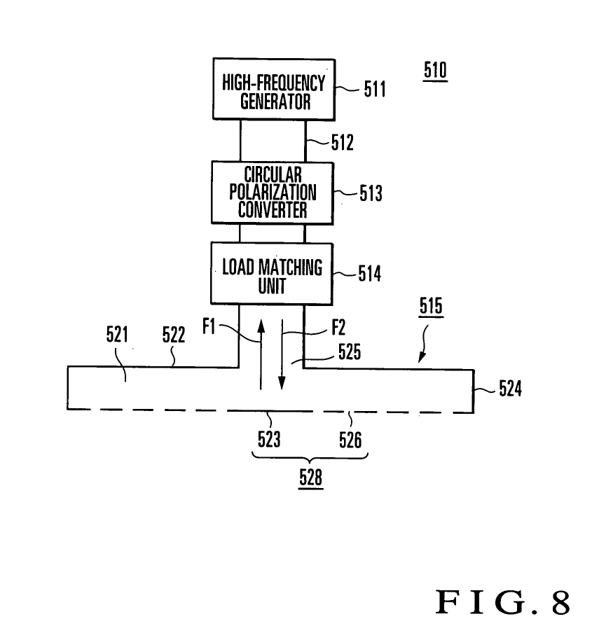

Referring to FIGS. 1, 2, and 5, the antenna surfaces 28 and 128 are flat plates. Alternatively, as shown in FIGS. 6A and 6B, an antenna surface 228A may form a circular cone. A high-frequency electromagnetic field F radiated (or leaking) from the circular conical antenna surface 228A becomes incident in an oblique direction on a plasma surface defined by a flat plate-like dielectric plate 7. Hence, the absorption efficiency of a plasma P for the high-frequency electromagnetic field F improves. The standing wave present between the antenna surface 228A and the plasma surface is weakened, so that the uniformity of the plasma distribution can be improved.

The antenna surface 228A forms an upwardly projecting circular cone. Alternatively, an antenna surface 228B which forms a downwardly projecting circular cone, as shown in FIG. 7, may be used. The antenna surfaces 228A and 228B may form projecting shapes other than circular cones.

The plasma device according to the present invention can be utilized as an etching device, plasma CVD device, ashing device, or the like.

1. A plasma processing device characterized by comprising:
a table for placing a target object thereon;
a processing vessel for accommodating said table; and
a slot antenna arranged to oppose said table to supply an electromagnetic field into said processing vessel, wherein
radiation coefficients of a plurality of slots formed in an antenna surface of said slot antenna increase monotonously in a radial direction of the antenna surface from a central portion of the antenna surface until a first intermediate portion on the way to a peripheral portion, and maintain values obtained at the first intermediate portion from the first intermediate portion toward the peripheral portion.

2. A plasma processing device according to claim 1, characterized in that lengths of the slots change monotonously from the central portion until the first intermediate portion of the antenna surface, and maintain lengths obtained at the first intermediate portion from the first intermediate portion toward the peripheral portion.

3. A plasma processing device according to claim 2, characterized in that when lengths L of the slots satisfy:
L≦λg/2
or
(N/2+¼)×λg≦L≦(N+1)×λg/2 (N is a natural number) where λg is a wavelength of an electromagnetic field in said slot antenna, the lengths of the slots increase monotonously from the central portion until the first intermediate portion.

4. A plasma processing device according to claim 2, characterized in that when lengths L of the slots satisfy:
L≦λg/2
or
(N/2+¼)×λg≦L≦(N+1)×λg/2 (N is a natural number) where λg is a wavelength of an electromagnetic field in said slot antenna, from an innermost slot of the antenna surface until an arbitrary slot of the antenna surface in the radial direction, a length of each slot is larger than that of a slot inside each slot, and from the arbitrary slot toward an outermost slot of the antenna surface, the length of each slot is equal to that of the arbitrary slot.

5. A plasma processing device according to claim 2, characterized in that when the lengths L of the slots satisfy:
N×λg/2≦L≦(N/2+¼)×λg (N is a natural number) where λg is a wavelength of an electromagnetic field in said slot antenna, the lengths of the slots decrease monotonously from the central portion until the first intermediate portion.

6. A plasma processing device according to claim 2, characterized in that when lengths L of the slots satisfy:
N×λg/2≦L≦(N/2+¼)×λg (N is a natural number) where λg is a wavelength of an electromagnetic field in said slot antenna, from an innermost slot of the antenna surface until an arbitrary slot of the antenna surface in the radial direction, a length of each slot is smaller than that of a slot inside each slot, and from the arbitrary slot toward an outermost slot of the antenna surface, the length of each slot is equal to that of the arbitrary slot.

7. A plasma processing device according to claim 1, characterized in that, in the radial direction of the antenna surface, the radiation coefficients of the slots maintain values obtained at the first intermediate portion from the first intermediate portion of the antenna surface until the second intermediate portion on the way to the peripheral portion, and decrease monotonously from the second intermediate portion until the peripheral portion.

8. A plasma processing device according to claim 7, characterized in that lengths of the slots change monotonously from the central portion until the first intermediate portion of the antenna surface, maintain lengths obtained at the first intermediate portion from the first intermediate portion until the second intermediate portion, and change monotonously from the second intermediate portion until the peripheral portion, inversely to the slots from the central portion until the first intermediate portion.

9. A plasma processing device according to claim 8, characterized in that when lengths L of the slots satisfy:
L≦λg/2
or
(N/2+¼)×λg≦L≦(N+1)×λg/2 (N is a natural number) where λg is a wavelength of an electromagnetic field in said slot antenna, the lengths of the slots decrease monotonously from the second intermediate portion until the peripheral portion.

10. A plasma processing device according to claim 8, characterized in that when the lengths L of the slots satisfy:
L≦λg/2
or
(N/2+¼)×λg≦L≦(N+1)×λg/2 (N is a natural number) where λg is a wavelength of an electromagnetic field in said slot antenna, from an innermost slot of the antenna surface until a slot at the first intermediate portion of the antenna surface in the radial direction, a length of each slot is larger than that of a slot inside each slot, from the slot at the first intermediate portion until a slot at the second intermediate portion in the radial direction, the length of each slot is equal to that of the slot at the first intermediate portion, and from the slot at the second intermediate portion until an outermost slot in the radial direction, the length of each slot is smaller than that of a slot inside each slot.

11. A plasma processing device according to claim 8, characterized in that when lengths L of the slots satisfy:
N×λg/2≦L≦(N/2+¼)×λg (N is a natural number) where λg is a wavelength of an electromagnetic field in said slot antenna, the lengths of the slots increase monotonously from the second intermediate portion until the peripheral portion.

12. A plasma processing device according to claim 8, characterized in that when lengths L of the slots satisfy:
N×λg/2≦L≦(N/2+¼)×λg (N is a natural number) where λg is a wavelength of an electromagnetic field in said slot antenna, from an innermost slot of the antenna surface until a slot at the first intermediate portion of the antenna surface in the radial direction, a length of each slot is smaller than that of a slot inside each slot, from the slot at the first intermediate portion until a slot at the second intermediate portion in the radial direction, the length of each slot is equal to that of the slot at the first intermediate portion, and from the slot at the second intermediate portion until an outermost slot in the radial direction, the length of each slot is larger than that of a slot inside each slot.

13. A plasma generating method characterized in that when an electromagnetic field is supplied into a processing vessel by using a slot antenna in which a plurality of slots are formed in an antenna surface thereof, to generate a plasma, radiation coefficients of the slots are increased monotonously from a central portion of the antenna surface until the first intermediate portion on the way to a peripheral portion, and values of the radiation coefficients obtained at the first intermediate portion are maintained from the first intermediate portion toward the peripheral portion.

14. A plasma generating method according to claim 13, characterized in that the values of the radiation coefficients obtained at the first intermediate portion are maintained from the first intermediate portion of the antenna surface until a second intermediate portion on the way to the peripheral portion in the radial direction of the antenna surface, and the radiation coefficients are decreased monotonously from the second intermediate portion until the peripheral portion.
